(19) United States
(12) Patent Application Publication
(10) Pub. No.: US 2024/0213101 A1
(43) Pub. Date: Jun. 27, 2024

(54) ELECTRONIC CIRCUIT WITH MOS TRANSISTORS AND MANUFACTURING METHOD

(71) Applicant: STMicroelectronics International N.V., Geneva (CH)

(72) Inventors: Brice ARRAZAT, Bouc-bel-air (FR); Christian RIVERO, Rousset (FR)

(73) Assignee: STMicroelectronics International N.V., Geneva (CH)

(21) Appl. No.: 18/535,882

(22) Filed: Dec. 11, 2023

(30) Foreign Application Priority Data
Dec. 22, 2022 (FR) 2214263

(51) Int. Cl. H01L 21/8238; H01L 21/762; H01L 27/092

(52) U.S. Cl. CPC H01L 21/823878; H01L 21/76224; H01L 27/092

(57) ABSTRACT

An electronic circuit includes a plurality of transistors including: at least one first MOS transistor of a first conductivity type arranged inside and on top of at least one first active area of a semiconductor substrate and at least one second MOS transistor of the second conductivity type arranged inside and on top of at least one second active area of the semiconductor substrate. Each first active area is delimited by a first insulating region which is recessed with respect to a first surface of the semiconductor substrate by a first depth. Each second active area is delimited by a second insulating region which is flush with the first surface of the semiconductor substrate, or which is recessed with respect to the first surface of the semiconductor substrate by a second depth smaller than the first depth.

### BACKGROUND

This application claims the priority benefit of French patent application No. 2214263, filed on Dec. 22, 2022, entitled “Circuit électronique à transistors MOS et procédé de fabrication,” which is hereby incorporated by reference to the maximum extent allowable by law.

### TECHNICAL FIELD

The present disclosure generally concerns electronic circuits, and in particular the manufacturing of NMOS and PMOS transistors of a same electronic circuit.

### DESCRIPTION OF THE RELATED ART

Metal oxide semiconductor field-effect transistors, or MOSFETs, are transistors including a conductive gate region electrically insulated from a semiconductor substrate, generally made of silicon, or from a well formed in a semiconductor substrate, by a dielectric layer called gate oxide or gate insulator, the gate region topping an active area including a source region, a drain region, and a channel-forming region between the source region and the drain region. A MOSFET may be designated with the term MOS transistor.

N-channel MOS transistors, or NMOS transistors, designate transistors having N-type doped source and drain regions, for example doped with arsenic or phosphorus atoms. P-channel MOS transistors, or PMOS transistors, designate transistors having P-type doped source and drain regions, for example doped with boron or indium atoms.

MOS transistors may be submitted to a dislocation phenomenon. A dislocation is a defect extended in the semiconductor substrate particularly when this substrate is made of single-crystal silicon. When it is located between the source region and the drain region, such a dislocation very strongly affects the functionality of the transistor, particularly resulting in a very high current of the transistor in the off state (OFF current), which can even entail a resistive behavior of the transistor.

Typically, a dislocation appears as the presence in the silicon of an additional crystalline half-plane ended by a gap. The origins of the occurrence of dislocations are multiples.

Among possible causes, one can mention the implantation of impurities at a high dose which will result in a local amorphization which, when it is followed by a too fast activation anneal, may create a dislocation. The type of impurities used during the doping may have an influence on the appearing of dislocations.

In this regard, it has been observed that dislocations essentially appear in NMOS transistors and more particularly in NMOS transistors having active areas of small size, in particular when arsenic is used as a dopant. Attempts of modifications of the type of dopant, of the dosage, and/or of the implantation energy to decrease the risk of occurrence of dislocations have however resulted in transistors having a performance decreased with respect to the expected performance, in particular when phosphorus is used.

Among other possible causes, one can also mention the stress induced in the active area of the transistor due to the presence of an insulation region, for example of shallow trench insulation (STI) type delimiting this active area. For example, the active area may be made of silicon (Si), and the insulating region may be a silicon dioxide (SiO₂) insulating trench, and the Si of the active area may be submitted to stress by the SiO₂ of the insulating trench located around the active area.

There is provided a method of manufacturing an NMOS transistor enabling to simply decrease the risk of occurrence of a dislocation in the active area of the transistor, in particular when NMOS and PMOS transistors of a same electronic circuit are manufactured on a same manufacturing line, according to a manufacturing method having some of its manufacturing steps similar for both types of transistors.

### BRIEF SUMMARY

It would be beneficial to provide methods of manufacturing the NMOS and PMOS transistors of a same electronic circuit, particularly enabling to decrease the risk of occurrence of dislocations of the NMOS transistors.

An embodiment overcomes all or part of the disadvantages of known electronic circuits with MOS transistors.

An embodiment provides an electronic circuit including a plurality of transistors including:
at least one first MOS transistor of a first conductivity type arranged inside and on top of at least one first active area of a semiconductor substrate;
at least one second MOS transistor of the second conductivity type arranged inside and on top of at least one second active area of the semiconductor substrate;
each first active area being delimited by a first insulating region which is recessed with respect to a first surface of the semiconductor substrate by a first depth; and
each second active area being delimited by a second insulating region which is flush with the surface of the semiconductor substrate, or which is recessed with respect to the first surface of the semiconductor substrate by a second depth smaller than the first depth.

An embodiment provides a method of manufacturing an electronic circuit including a plurality of transistors including:
at least one first MOS transistor of a first conductivity type arranged inside and on top of at least one first active area of a semiconductor substrate;
at least one second MOS transistor of the second conductivity type arranged inside and on top of at least one second active area of the semiconductor substrate;
the manufacturing method including the forming of at least one first and one second insulating regions configured so that:
   each first active area is delimited by a first insulating region recessed with respect to a first surface of the semiconductor substrate by a first depth; and
   each second active area is delimited by a second insulating region flush with the first surface of the semiconductor substrate, or recessed with respect to the first surface of the semiconductor substrate by a second depth smaller than the first depth.

According to an embodiment, the first surface of the semiconductor substrate is topped with gate regions of the at least one first MOS transistor and of the at least one second MOS transistor, each gate region being insulated from the semiconductor substrate by a gate insulator layer.

According to an embodiment, the at least one first and one second insulating regions are trench insulations, for example shallow trench insulations.

According to an embodiment, the at least one first and one second insulating regions are adjacent.

As a variant, the at least one first and one second insulating regions may be separate.

According to an embodiment, the first depth is greater than or equal to 120 Å, and the second depth is smaller than 120 Å.

According to an embodiment, the gate region of at least one transistor among the plurality of transistors includes at least one counter-doping area of a conductivity type opposite to the conductivity type of said at least one transistor, said at least one counter-doping area being positioned and sized to attenuate the hump effect of said at least one transistor, for example said at least one counter-doping area is positioned at the level of an overlapping area between the gate region and the active area of said at least one transistor.

According to a specific embodiment, the at least one transistor is the at least one first MOS transistor.

According to an embodiment, the first conductivity type is type N, each first MOS transistor being an NMOS transistor, and the second conductivity type is type P, each second MOS transistor being a PMOS transistor.

According to an embodiment, the semiconductor substrate includes silicon, and the at least one first and one second insulating regions include a silicon oxide, for example silicon dioxide.

According to an embodiment, the electronic circuit is contained in a non-volatile memory, for example an electrically erasable and programmable non-volatile memory.

According to an embodiment, the forming of the at least one first and one second insulating regions includes the forming of the at least one second insulating region; and then the forming of the at least one first insulating region.

According to an embodiment, the forming of the at least one first and one second insulating regions includes a step of etching of initial insulating regions delimiting the first active area and the second active area, said etch step including:
a first etching of the initial insulating regions from the first surface of the semiconductor substrate and down to the second depth, to form second insulating regions; then
a second etching of at least one among the second insulating regions, from the first surface of the semiconductor substrate and down to the first depth, to form the at least one first insulating region; the second etching being performed through a second etch mask configured to access each first transistor and mask each second transistor.

By “initial insulating regions,” there is meant insulating regions initially formed in the semiconductor substrate. For example, these initial insulating regions are substantially flush with the first surface of the semiconductor substrate.

According to an embodiment, the first etching is performed through a first etch mask configured to access each first transistor and each second transistor.

An embodiment provides an integrated circuit including any of the previously-described electronic circuits.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A shows, in a cross-section view, an example of an electronic circuit including NMOS and PMOS transistors formed inside and on top of a same semiconductor substrate;

FIG. 1B shows, in a cross-section view, a variant of the electronic circuit of FIG. 1A;

FIG. 1C shows, in a top view, one of the transistors of the electronic circuit of FIG. 1B;

FIG. 2 shows an example of a method of manufacturing an electronic circuit similar to the electronic circuit of FIG. 1A or of FIG. 1B;

FIG. 3 shows an electronic circuit according to an embodiment including NMOS and PMOS transistors formed inside and on top of a same semiconductor substrate; and

FIG. 4A shows a manufacturing method according to an embodiment of an electronic circuit including NMOS and PMOS transistors inside and on top of a same semiconductor substrate;

FIG. 4B shows a variant of the manufacturing method of FIG. 4A, according to an embodiment;

FIG. 5A and FIG. 5B illustrate examples of positioning of etch masks and/or of openings of the etch masks during an etch step of a manufacturing method according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, not all the steps of the MOS transistor manufacturing method have been described, being implementable with usual methods of microelectronics. Similarly, not all the details of the MOS transistors have been described. In particular, the interconnection contacts and circuits of the transistors have not been shown. Further, the possible applications of the described transistors have not all been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front,” “back,” “top,” “bottom,” “left,”, “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the drawings.

Unless specified otherwise, the expressions “about,” “approximately,” “substantially,” and “in the order of” signify plus or minus 10%, preferably of plus or minus 5%.

In the following description, in order to lighten it, a MOSFET-type transistor may be designated with the term MOS transistor, or transistor.

When reference is made to an “active area,” it is referred to an area of a semiconductor substrate of a transistor, for example, an area delimited by insulating regions. An active area typically includes a source region, a drain region, and a channel-forming region, or channel region, between the source region and the drain region. The active area may be formed in the semiconductor substrate or in a well formed in the semiconductor substrate.

A semiconductor substrate may be a solid substrate, for example made of silicon, or a semiconductor layer of a substrate of silicon on insulator type (SOI).

In the following description, a length corresponds to a dimension in a first direction, corresponding to the X direction indicated in the drawings, of a main plane XY. The main plane substantially corresponds to the main plane of the semiconductor substrate inside and on top of which the transistor is formed. The first direction corresponds to a direction parallel to the conduction direction of the transistor. A width corresponds to a dimension in a second direction of main plane XY, corresponding to the Y direction indicated in the drawings, orthogonal to the first direction. A thickness or a depth corresponds to a dimension in the direction perpendicular to main plane XY, corresponding to the vertical Z direction indicated in the drawings.

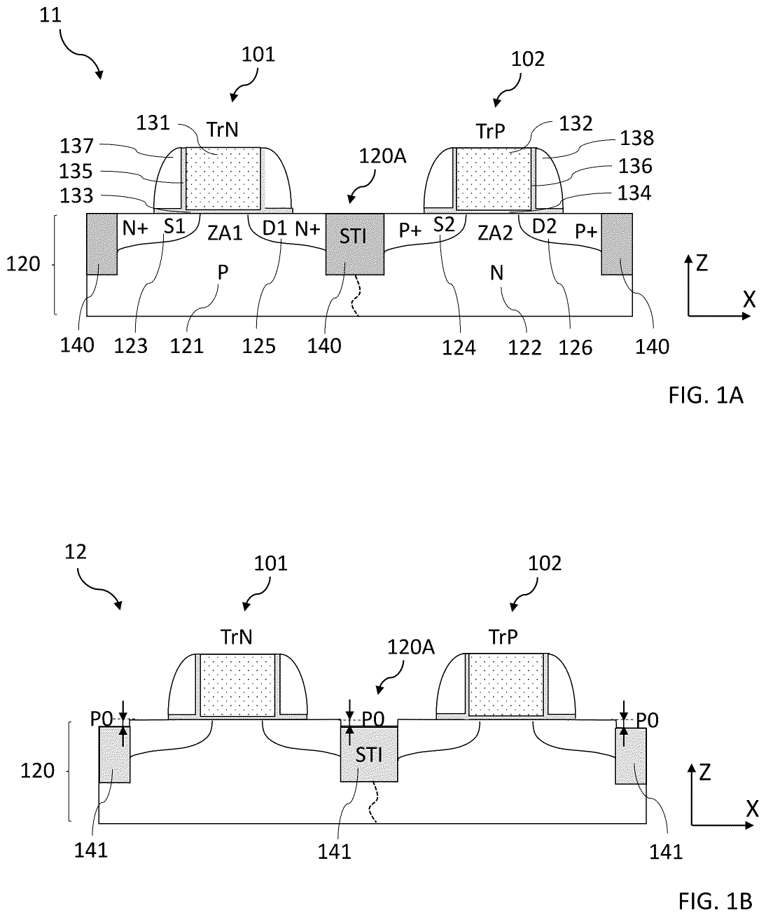

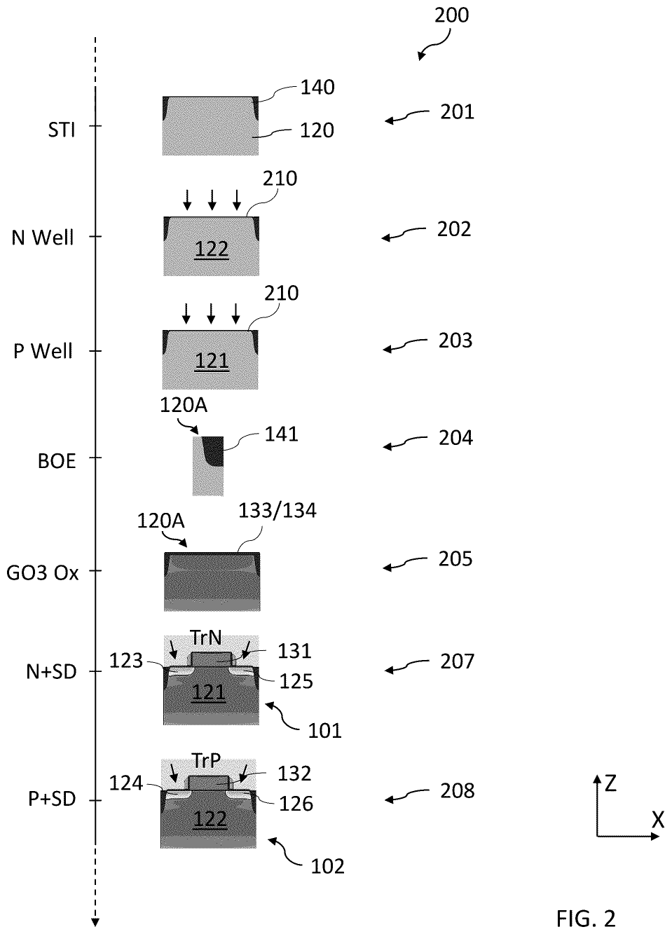

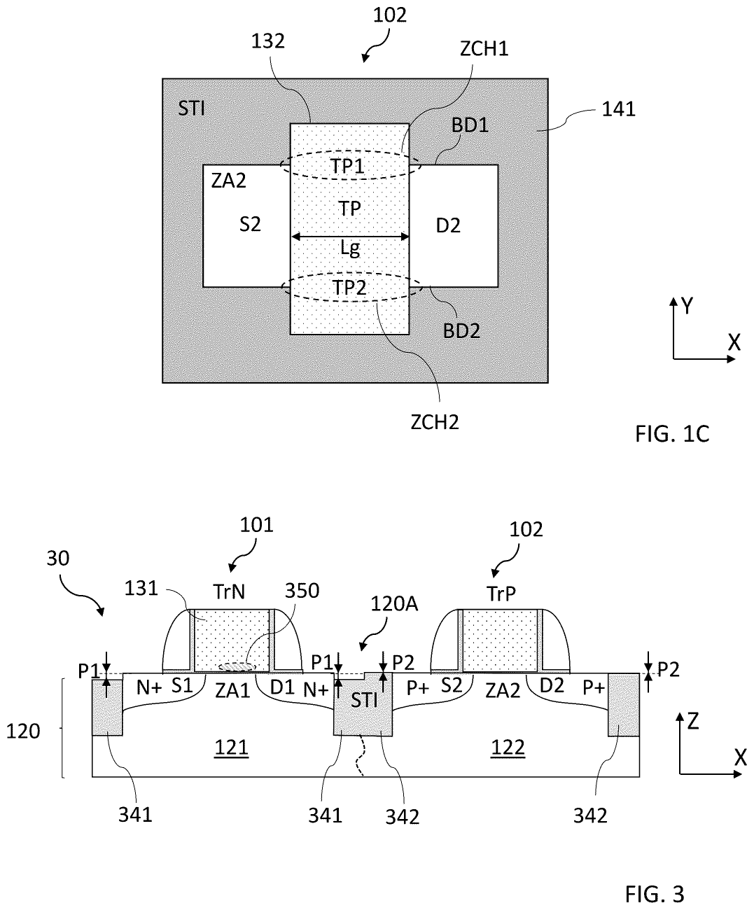

FIG. 1A shows an example of an electronic circuit 11 including two adjacent transistors, a transistor 101 (first transistor) of NMOS type (TrN) and a transistor 102 (second transistor) of PMOS type (TrP), formed inside and on top of a semiconductor substrate 120.

NMOS transistor 101 includes, within semiconductor substrate 120, a P-type well 121, a first active area ZA1 delimited in well 121 by one or a plurality of insulating regions 140, for example of shallow trench insulation (STI) type. First active area ZA1 includes a source region 123 (S1) and a drain region 125 (D1) which are heavily N-type doped (N+), as well as a channel-forming region between the source region and the drain region.

NMOS transistor 101 also includes, on the upper surface 120A (first surface) of substrate 120, above first active area ZA1, a gate region 131 insulated by a gate oxide 133. The sides of gate region 131, as well as a portion of substrate 120 around the gate region, are covered with an oxide layer 135, itself covered with an insulating spacer 137.

PMOS transistor 102 includes, within semiconductor substrate 120, an N-type well 122, a second active area ZA2 delimited in well 122 by one or a plurality of insulating regions 140. Second active area ZA2 includes a source region 124 (S2) and a drain region 126 (D2), which are heavily P-type doped (P+), as well as a channel-forming region between the source region and the drain region.

PMOS transistor 102 also includes, on the upper surface 120A (first surface) of substrate 120, above second active area ZA2, a gate region 132 insulated by a gate oxide 134. The sides of gate region 132, as well as a portion of substrate 120 around the gate region, are covered with an oxide layer 136, itself covered with an insulating spacer 138.

For example, the active areas are made of silicon (Si). For example, the insulating regions are trench insulations made of silicon dioxide (SiO₂). For example, the gate regions are made of polysilicon. The gate regions may be of simple gate type or of multiple-gate, for example of floating-gate type.

To decrease the risk of dislocation, it may be desired to decrease the stress induced by the insulating regions on the active areas, for example by decreasing the volumes of insulator in these insulating regions.

Given that the insulating regions particularly have the function of insulating NMOS and PMOS transistors 101 and 102 from each other, and particular the P and N wells 121 and 122 of these respective transistors, it is generally avoided to decrease the depth of the insulating regions, for example, to avoid causing or increasing leakage currents between the active areas delimited by these insulating regions. The volumes of the insulating regions can be decreased by removing a portion of insulator of each insulating region from the upper surface 120A of semiconductor substrate 120.

FIG. 1B shows, in a cross-section view, a variant of the electronic circuit of FIG. 1A. The electronic circuit 12 of FIG. 1B differs from the electronic circuit 11 of FIG. 1A in that insulating regions 141 are recessed (have been etched) with respect to the upper surface 120A of substrate 120 by a non-zero depth P0, for example equal to approximately 230 Å. In other words, a portion of insulator of each insulating region 141 has been removed down to a depth P0 from the upper surface 120A of substrate 120. This insulator portion is removed around NMOS and PMOS transistors 101 and 102.

FIG. 1C shows, in a top view, the PMOS transistor 102 of the electronic circuit of FIG. 1B.

Gate region 132 has a length Lg in the X conduction direction of the transistor, and it also extends transversely to the active area ZA2 of transistor 102 in the Y direction, perpendicular to the X direction, for example to provide a contact area for said gate region. Thus, gate region 132 overlaps two opposite edges BD1 and BD2 of active area ZA2 at the level of two overlapping areas ZCH1 and ZCH2, respectively. In the overlapping areas, a non-uniform thickness of gate oxide 134 may form, and parasitic transistors TP1 and TP2 may form at the edges BD1 and BD2 of active area ZA2, with between these parasitic transistors a central transistor TP having an expected operation. Parasitic transistors TP1 and TP2 have a threshold voltage lower than that of central transistor TP. Since the threshold voltage of the parasitic transistors is lower than that of the central transistor, the threshold voltage of transistor 102 is lower than that expected.

This effect is known under the term hump effect, and it is generally desired to avoid it and/or to correct it. In the foregoing description, this phenomenon has been described in relation with the PMOS transistor, but may also occur for the NMOS transistor.

Further, the more insulating region 141 is recessed with respect to the upper surface 120A of substrate 120, that is, the greater the depth P0 (the more it has been etched), the more the hump effect may occur.

In other words, it may be desired to improve the performance of the NMOS transistor, and in particular to decrease the probability of occurrence of dislocations in the active area of the NMOS transistor by varying depth P0, dislocations essentially appearing in NMOS transistors, but this may contribute to degrading the performance of the PMOS transistor, in particular to increasing the hump effect on the PMOS transistor.

This can be particularly explained in that the removal of the insulator portions of the insulating regions may be performed by using a same step of a method of manufacturing an electronic circuit having NMOS and PMOS transistors formed inside and on top of a same semiconductor substrate. The NMOS and PMOS transistors of a same electronic circuit may indeed be manufactured on a same manufacturing line, according to a manufacturing method where the maximum number of manufacturing steps is similar for both types of transistors, particularly for reasons of manufacturing cost. In other words, the NMOS and PMOS transistors of an electronic circuit may be submitted to the same steps of a manufacturing method, except for the doping steps, for example the doping of the wells, and the doping of the source and drain regions, which are different according to whether the transistor has an N channel or a P channel, these steps generally requiring dedicated implantation masks so that only the regions to be doped, of type N or of type P, are effectively doped. This is illustrated in relation with FIG. 2 described hereafter.

FIG. 2 shows an example of a method 200 of manufacturing an electronic circuit including NMOS and PMOS transistors formed inside and on top of a same semiconductor substrate, capable of applying to the manufacturing of the electronic circuit 11 of FIG. 1A or of the electronic circuit 12 of FIG. 1B. The elements identical to those previously described are identified by the same reference numerals. Not all the manufacturing steps have been detailed, only the steps useful for the understanding of the issue have been shown and only some are detailed in the following description, the non-detailed steps being implementable with usual methods of microelectronics. The implantation masks are not shown, their description being sufficient to understand how they can be positioned.

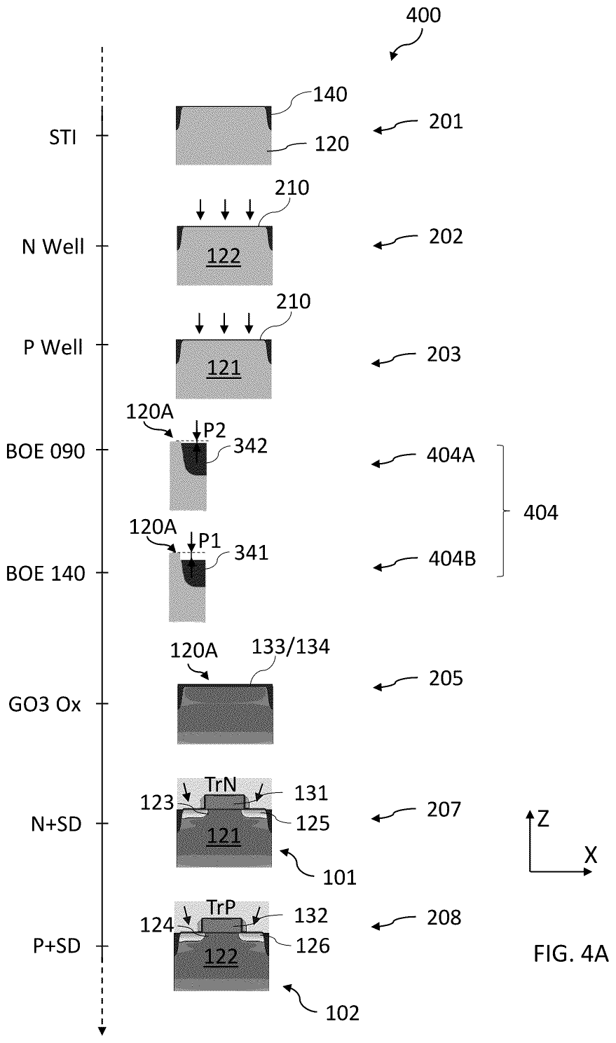

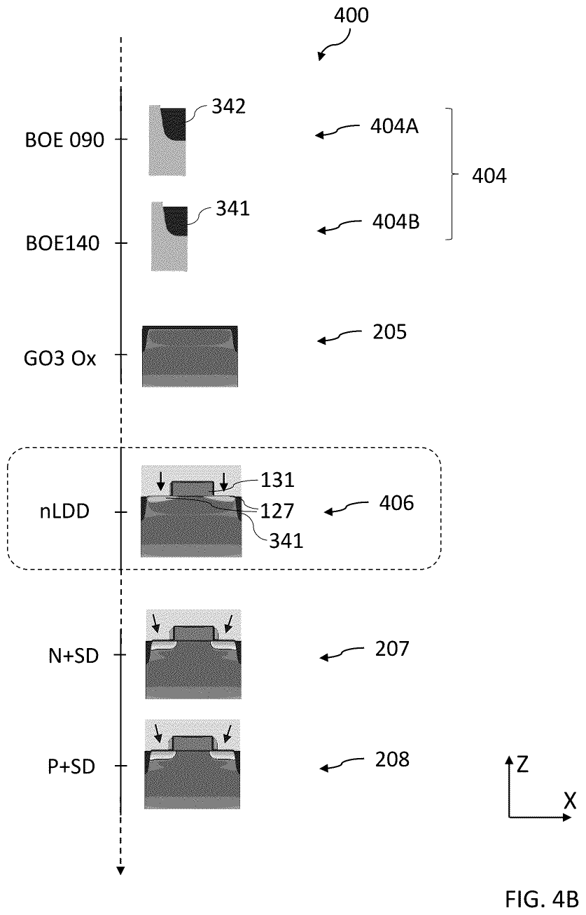

In FIGS. 2, 4A, and 4B, the steps are shown on a time axis.

After a step 201 (STI) of forming of insulating regions 140 (initial insulating regions, non-etched) in a semiconductor substrate 120, for example of trench insulations, to insulate the future NMOS and PMOS transistors, a step 202 (N Well) of N-type doping is carried out to form N-type well 122 for the PMOS transistor, by using an implantation mask adapted to hiding the regions not to be N doped during this step, after which a step 203 (P well) of P-type doping is carried out to form P-type well 121 for the NMOS transistor, by using an implantation mask adapted to hiding the regions not to be P doped during this step. Each doping step is typically carried out by ion implantation.

These doping steps to form the wells are generally carried out through a dielectric layer 210 of ONO type, for “Oxide Nitride Oxide.” Such a dielectric layer may, for example, be used to insulate a polysilicon layer intended to form all or part of a gate region of one or a plurality of other transistors positioned on top of and inside another portion of the semiconductor substrate.

On the portions of semiconductor substrate 120 delimited by initial insulating regions 140, dielectric layer 210 is removed, typically by means of a dry etching, followed by a wet etching step 204 (BOE). Wet etching step 204 is generally performed by means of a solution of hydrofluoric acid (HF), to remove the residual oxide on the upper surface 120A of semiconductor substrate 120, and this, for each of the future NMOS and PMOS transistors. This wet etching step may be designated with the term BOE, for “Buffered Oxide Etch.”

During wet etching step 204, an insulator portion of the initial insulating regions 140 may be removed down to a given depth, for example depth P0, resulting in insulating regions 141 recessed with respect to the upper surface 120A of substrate 120. The depth of the etching of the insulator of insulating regions 141 may be controlled during this wet etching step, particularly by controlling the time period for which it is placed in contact with the etching solution, for example according to whether it is rather aimed at limiting the dislocation phenomenon, or rather at decreasing the hump effect. For example, the etching depth in the insulating regions is selected as equal to approximately 90 Å when it is desired to prefer the decrease of the hump effect, or is selected as equal to approximately 230 Å when it is desired to prefer the decrease of the dislocation phenomenon.

Then, a step 205 (GO3 Ox) of oxidation of a portion of semiconductor substrate 120 from its upper surface 120A is carried out to form gate oxide layers 133/134, on which the gate regions of the future NMOS and PMOS transistors will then be formed. During this oxidation step, the implants deposited during the previously-described doping steps 202, 203 will diffuse into semiconductor substrate 120.

Then, after the forming of the gate regions 131/132 of the NMOS and PMOS transistors, of the oxide layer, and of the insulating spacer on the sides of each gate region (steps not shown), a step 207 (N+SD) of heavy N-type doping is carried out to form the source 123 and drain 125 regions of NMOS transistor 101 (TrN) by using an implantation mask adapted to hiding the regions not to be N doped during this step. Then, a step 208 (P+SD) of heavy P-type doping is carried out to form the source 124 and drain 126 regions of PMOS transistor 102 (TrP) by using an implantation mask adapted to hiding the regions not to be P doped during this step.

A disadvantage of this manufacturing method is that the NMOS and PMOS transistors are submitted to the same wet etching step, which explains that by varying the wet etching parameters and particularly by increasing depth P0, one may indeed decrease the dislocations which essentially appear in the NMOS transistor, but this may also contribute to degrading the performance of the PMOS transistor, in particular to increasing the hump effect on the PMOS transistor.

The inventors provide an electronic circuit including NMOS and PMOS transistors, as well as a method of manufacturing such an electronic circuit, enabling to address the previously-described improvement needs, and to overcome all or part of the disadvantages of the previously-described electronic circuits and manufacturing methods. In particular, the inventors provide an electronic circuit including NMOS and PMOS transistors, as well as a method of manufacturing such an electronic circuit which enables to improve the performance of the NMOS transistor, and this, without degrading the performance of the PMOS transistor, or conversely.

Embodiments of electronic circuits and of methods of manufacturing electronic circuits will be described hereafter. The described embodiments are non-limiting and various variants will occur to those skilled in the art based on the indications of the present description.

FIG. 3 shows an electronic circuit 30 according to an embodiment, including adjacent NMOS and PMOS transistors formed inside and on top of a same semiconductor substrate 120.

Electronic circuit 30 can be distinguished from the electronic circuits 11, 12 of FIGS. 1A and 1B essentially in that the insulating regions include a first insulating region 341 delimiting the active area ZA1 of NMOS transistor 101 and a second insulating region 342 delimiting the active area ZA2 of PMOS transistor 102. First insulating region 341 is recessed (etched) from the upper surface 120A of semiconductor substrate 120 by a first non-zero depth P1. Second insulating region 342 may also be recessed (etched) with respect to the upper surface 120A of semiconductor substrate 120 by a second depth P2 smaller than first depth P1, or even much smaller. For example, second depth P2 is substantially zero, as shown, where it can be seen that second insulating region 342 is substantially flush with the upper surface 120A of semiconductor substrate 120. In other words, there has been removed, for example etched, more insulator, from the upper surface 120A of semiconductor substrate 120, around the NMOS transistor than around the PMOS transistor.

Thus, the performance of the NMOS transistor can be improved, and in particular the probability of occurrence of dislocations in the active area of the NMOS transistor can be decreased, while avoiding degrading the performance of the PMOS transistor, in particular while avoiding increasing the hump effect on the PMOS transistor.

For example, first depth P1 is greater than or equal to 120 Å, for example equal to approximately 230 Å, and second depth P2 is smaller than 120 Å, for example equal to approximately 90 Å.

In the shown example, the first and second insulating regions are adjacent, that is, form an insulating region continuous with a step between the NMOS transistor and the PMOS transistor. As a variant, the first and second insulating regions may be separate.

Optionally, in the case where the hump effect occurs or is increased in NMOS transistor 101, particularly due to the etching of first insulating region 341, it may be desired to attenuate or to correct the hump effect. A solution to attenuate this hump effect is to locally counter-dope, for example by ion implantation, the gate region 131 of NMOS transistor 101, preferably in the overlapping area(s) where the parasitic transistor(s) are formed. In other words, optionally, at least one local counter-doping area 350 of the conductivity type opposite to the conductivity of the transistor may be provided, in the illustrated case a P-type counter doping area, in the gate region of said transistor, this counter-doping area being positioned and sized to attenuate the hump effect of the NMOS transistor.

The other characteristics of electronic circuit 30 May be similar to those of the electronic circuits 11, 12 of FIGS. 1A and 1B, particularly the characteristics of the NMOS and PMOS transistors.

FIG. 4A shows a manufacturing method 400 according to an embodiment of an electronic circuit including NMOS and PMOS transistors formed inside and on top of a same semiconductor substrate, capable of applying to the manufacturing of the electronic circuit 30 of FIG. 3. The elements identical to those previously described are identified by the same reference numerals.

The manufacturing method 400 of FIG. 4A can be distinguished from the manufacturing method 200 of FIG. 2 essentially in that wet etching step 404 includes two etchings:
a first etching 404A (BOE 090) where the initial insulating regions 140 are etched down to a same depth corresponding to second depth P2, enabling to form second insulating regions 342; this first etching 404A may be performed through a first etch mask including an opening enabling to access the NMOS and PMOS transistors, or may be performed with no etch mask, for example if it is not necessary to mask other components of the electronic circuit during this first etching;
a second etching 404B (BOE 230) where the second insulating regions 342 which are not protected by a second etch mask are etched, down to a first depth P1 greater than second depth P2, enabling to transform at least one of the second insulating regions into first insulating region 341 around the NMOS transistor; in other words, in this second etching, the first etching is completed around the NMOS transistor by a second etching down to a depth equal to the difference between first depth P1 and second depth P2.

The second etch mask is configured to mask at least the PMOS transistor and includes an opening enabling to access at least the NMOS transistor. Thus, second insulating region 342 is kept around the PMOS transistor.

When it is indicated that an opening of an etch mask enables to access an NMOS and/or PMOS transistor, this means that this opening enables to access said transistor and the surrounding insulating region.

For example, the first etching 404A is adapted to intentionally etching the initial insulating regions 140 down to second depth P2.

As a variant, the first etching 404A may correspond to the removal of the residual oxide on the semiconductor substrate, without intentionally etching initial insulating regions 140, for example in the case where second depth P2 is substantially zero.

The other steps of manufacturing method 400 may be similar to those of the manufacturing method 200 of FIG. 2.

FIG. 4B shows a variant of the manufacturing method of FIG. 4A, where there has further been shown a step 406 (nLDD) of light doping of semiconductor substrate 120 to form a lightly-doped drain region 127, known under the term LDD, between gate region 131 and the first insulating regions 341 of the NMOS transistor. This light doping step 406 is carried out after the step 205 allowing the forming of the gate region 131 of the NMOS transistor, and generally after the deposition of the oxide layer on the sides of the gate region, but before the forming of the insulating spacer (steps not shown), and thus before the step 207 of heavy N-type doping. Gate region 131, with generally the oxide layer on its sides, is used as a protection mask during the operation of light doping of the semiconductor substrate to form this LDD region 127 of type N.

Another implantation mask, or LDD mask, is further provided to hide the regions not to be N doped during this step. This LDD mask may advantageously be used as a second etch mask to carry out the second etching sub-step, which is carried out before light doping step 406. This enables to avoid the manufacturing of an additional mask.

There generally also exists a step of forming of a lightly-doped drain region for the PMOS transistor (not shown).

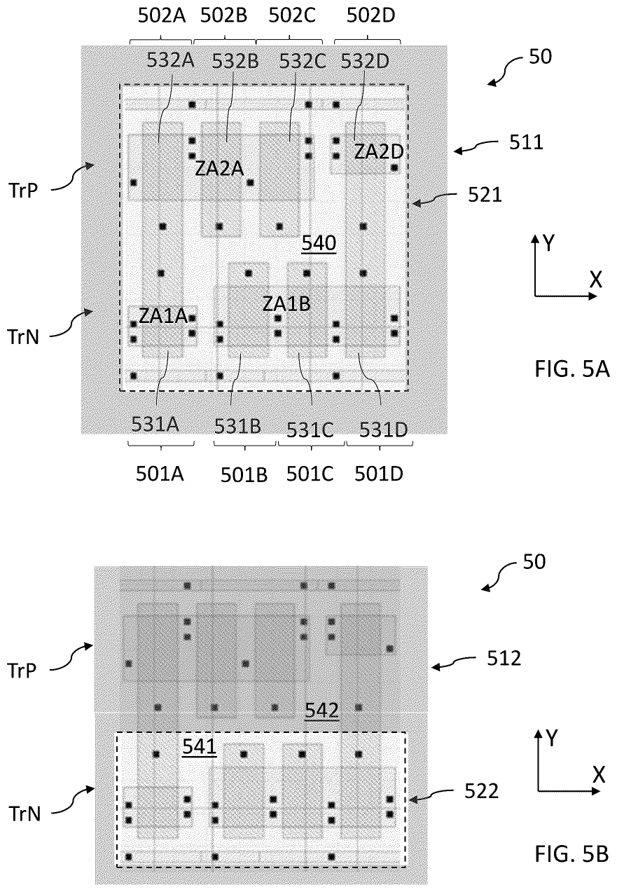

FIG. 5A and FIG. 5B illustrate examples of positioning of etch masks and/or of openings of the etch masks during an etch step of a manufacturing method according to an embodiment.

FIGS. 5A and 5B correspond, for example, to layouts of a plurality of transistors 501A-501D, 502A-502D in an electronic circuit 50. Transistors 501A-501D (TrN) correspond to NMOS transistors, and there is a plurality of NMOS transistors next to one another in the X direction. Transistors 502A-502D (TrP) correspond to PMOS transistors, and there is a plurality of PMOS transistors next to one another in the X direction. The plurality of NMOS transistors is adjacent to the plurality of PMOS transistors in the Y direction.

The active area of each NMOS transistor is topped with a gate region 531A-531D. The active areas ZA1B of NMOS transistors 501B-501D are continuous, that is, not insulated from one another by insulating regions, and the active area ZA1A of NMOS transistor 501A is entirely insulated by an insulating region.

The active area of each PMOS transistor is topped with a gate region 532A-532D. The active areas ZA2A of PMOS transistors 502A-502C are continuous, that is, not insulated from one another by insulating regions, and the active area ZA2D of PMOS transistor 502D is entirely insulated by an insulating region.

As shown in FIG. 5A, the gate regions 531A, 532A of the respective NMOS and PMOS transistors 501A, 502A may be common, or continuous, and even for the gate regions 531D, 532D of the respective NMOS and PMOS transistors 501D, 502D.

The structure shown in FIG. 5A includes initial insulating regions 540 around the active areas of the NMOS transistors, around the active areas of the PMOS transistors, and between the NMOS and PMOS transistors. A first etch mask 511 has been positioned above electronic circuit 50, first etch mask 511 having a first opening 521 enabling to access the NMOS and PMOS transistors (including portions of the surrounding insulating regions). This first etch mask enables to implement the first etching sub-step. Alternatively, first etch mask 511 may be omitted, for example if it is not necessary to mask other transistors or other electronic components of the electronic circuit 50 during this first etching.

In the structure shown in FIG. 5B, a second etch mask 512 has been positioned above electronic circuit 50, second etch mask 512 having a second opening 522 enabling to access the NMOS transistors (including portions of the surrounding insulating regions), and to mask the PMOS transistors. This second etch mask enables to implement the second etching sub-step.

The embodiments may apply to EEPROM-type memories including NMOS—and PMOS—type transistors, for example EEPROM-type memories formed on an integrated circuit. The embodiments may also apply to FLASH memories, or any other technology with no integrated memory such as digital technologies or the like. More generally, the embodiments may apply when it is desired to improve the performance of an NMOS-type transistor without degrading those of a PMOS-type transistor of the same electronic circuit, or conversely.

Various embodiments and variants have been described. Those skilled in the art will understand that certain features of these various embodiments and variants may be combined, and other variants will occur to those skilled in the art. In particular, there has been shown in FIG. 3 an electronic circuit with an NMOS transistor and a PMOS transistor positioned next to each other, and insulated from each other, in the first X direction. As a variant, the NMOS and PMOS transistors may be positioned next to each other, and insulated from each other, in another direction of the main plane, for example in the second Y direction, as shown in FIGS. 5A and 5B. As a variant, the electronic circuit may include a plurality of NMOS transistors and/or a plurality of PMOS transistors, where some among the NMOS and PMOS transistors may be positioned next to each other, and insulated from each other, in the first direction, and others among the NMOS and PMOS transistors may be positioned next to each other, and insulated from each other, in the second direction. The active areas and/or the gate regions may be common to a plurality of transistors. The electronic circuit may also include other types of transistors, and/or other electronic components.

Finally, the practical implementation of the described embodiments and variants is within the abilities of those skilled in the art based on the functional indications given hereabove.

Electronic circuit (30) including a plurality of transistors may be summarized as including at least one first MOS transistor (101) of a first conductivity type arranged inside and on top of at least one first active area (ZA1) of a semiconductor substrate (120); at least one second MOS transistor (102) of the second conductivity type arranged inside and on top of at least one second active area (ZA2) of the semiconductor substrate (120); each first active area (ZA1) being delimited by a first insulating region (341) which is recessed with respect to a first surface (120A) of the semiconductor substrate (120) by a first depth (P1); and each second active area (ZA2) being delimited by a second insulating region (342) which is flush with the first surface of the semiconductor substrate, or which is recessed with respect to the first surface of the semiconductor substrate by a second depth (P2) smaller than the first depth (P1).

Method of manufacturing (400) an electronic circuit including a plurality of transistors may be summarized as including at least one first MOS transistor (101) of a first conductivity type arranged inside and on top of at least one first active area (ZA1) of a semiconductor substrate (120); at least one second MOS transistor (102) of the second conductivity type arranged inside and on top of at least one second active area (ZA2) of the semiconductor substrate (120); the manufacturing method including the forming of at least one first (341) and one second (342) insulating regions configured so that: each first active area (ZA1) is delimited by a first insulating region (341) recessed with respect to a first surface (120A) du semiconductor substrate (120) by a first depth (P1); and each second active area (ZA2) is delimited by a second insulating region (342) flush with the first surface of the semiconductor substrate, or recessed with respect to the first surface of the semiconductor substrate by a second depth (P2) smaller than the first depth (P1).

The first surface (120A) of the semiconductor substrate (120) may be topped with gate regions (131, 132) of the at least one first MOS transistor (101) and of the at least one second MOS transistor (102), each gate region being insulated from the semiconductor substrate by a gate insulator layer (133, 134).

The at least one first and one second insulating regions may be trench insulations, for example shallow trench insulations.

The at least one first and one second insulating regions may be adjacent.

The first depth (P1) may be greater than or equal to 120 Å, and the second depth (P2) may be smaller than 120 Å.

The gate region of at least one transistor among the plurality of transistors may include at least one counter-doping area (350) of a conductivity type opposite to the conductivity type of said at least one transistor, said at least one counter-doping area being positioned and sized to attenuate the hump effect of said at least one transistor, for example said at least one counter-doping area may be positioned at the level of an overlapping area between the gate region and the active area of said at least one transistor.

The at least one transistor may be the at least one first MOS transistor (101).

The first conductivity type may be type N, each first MOS transistor being an NMOS transistor, and the second conductivity type may be type P, each second MOS transistor being a PMOS transistor.

The semiconductor substrate may include silicon, and the at least one first and one second insulating regions may include a silicon oxide, for example silicon dioxide.

The electronic circuit may be contained in a non-volatile memory, for example an electrically erasable and programmable non-volatile memory.

The forming of the at least one first and one second insulating regions may include the forming of the at least one second insulating region (342); and then the forming of the at least one first insulating region (341).

The forming of the at least one first and one second insulating regions may include a step of etching of initial insulating regions (140) delimiting the first active area (ZA1) and the second active area (ZA2), said etch step including: a first etching (404A) of the initial insulating regions (140) from the first surface (120A) of the semiconductor substrate (120) and down to the second depth (P2), to form second insulating regions (342); then a second etching (404B) of at least one among the second insulating regions (342), from the first surface (120A) of the semiconductor substrate (120) and down to the first depth (P1), to form the at least one first insulating region (341); the second etching being performed through a second etch mask (512) configured to access each first transistor and mask each second transistor.

The first etching may be performed through a first etch mask (511) configured to access each first transistor and each second transistor.

An integrated circuit may be summarized as including an electronic circuit.

In one embodiment, a method includes forming a first trench insulation in a semiconductor substrate delimiting a first active area of the semiconductor substrate, forming a second trench insulation in the semiconductor substrate delimiting a second active area of the semiconductor substrate, and recessing a top surface of the first trench insulation to a first depth below a top surface of the semiconductor substrate. The method includes recessing a top surface of the second trench insulation to a second depth below the top surface of the semiconductor substrate, forming a first MOS transistor of a first conductivity type at the first active region, and forming a second MOS transistor of a second conductivity type at the second active region.

In one embodiment, the method includes recessing the top surface of the second trench insulation after recessing the top surface of the first trench insulation.

In one embodiment, the method includes forming the first and second trench insulations in a same process, recessing the top surface of the first trench insulation to the first depth with a first etching process, and recessing the top surface of the second trench insulation to the second depth with a second etching process after the first etching process while the first trench insulation is covered by a first mask and the second trench insulation is exposed through the first mask.

In one embodiment, the first and second trench insulations are exposed to the first etching process through a second mask.

In one embodiment, the first MOS transistor is a PMOS transistor and the second MOS transistor is an NMOS transistor.

In one embodiment, the first trench insulation abuts the second trench insulation.

In one embodiment, an integrated circuit includes a semiconductor substrate including a first active area and a second active area, a first transistor of a first conductivity type at the first active region, a second transistor of a second conductivity type at the second active area; and a trench insulation defining a boundary between the first active area and the second active area and including a top surface with a step such that a first portion of the top surface of the trench insulation next to the first active area is lower than a second portion of the top surface of the trench insulation than to next to the second active area.

In one embodiment, the first transistor is an NMOS transistor and the second transistor is a PMOS transistor.

In one embodiment, the top surface of the trench insulation is below a top surface of the semiconductor substrate near the first active area, wherein the top surface of the trench insulation is substantially coplanar with the top surface of the semiconductor substrate near the second active area.

In one embodiment, the trench insulation is silicon oxide.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic circuit, comprising a plurality of transistors including:
at least one first MOS transistor of a first conductivity type arranged inside and on top of at least one first active area of a semiconductor substrate;
at least one second MOS transistor of the second conductivity type arranged inside and on top of at least one second active area of the semiconductor substrate;
each first active area being delimited by a first insulating region which is recessed with respect to a first surface of the semiconductor substrate by a first depth; and
each second active area being delimited by a second insulating region which is flush with the first surface of the semiconductor substrate, or which is recessed with respect to the first surface of the semiconductor substrate by a second depth smaller than the first depth.

2. The electronic circuit according to claim 1, wherein the first surface of the semiconductor substrate is topped with gate regions of the at least one first MOS transistor and of the at least one second MOS transistor, each gate region being insulated from the semiconductor substrate by a gate insulator layer.

3. The electronic circuit according to claim 1, wherein the at least one first and one second insulating regions are shallow trench insulations.

4. The electronic circuit according to claim 1, wherein the at least one first and one second insulating regions are adjacent to each other.

5. The electronic circuit according to claim 1, wherein the first depth is greater than or equal to 120 Å, and the second depth is smaller than 120 Å.

6. The electronic circuit according to claim 1, wherein the gate region of at least one transistor among the plurality of transistors includes at least one counter-doping area of a conductivity type opposite to the conductivity type of said at least one transistor, said at least one counter-doping area being positioned and sized to attenuate the hump effect of said at least one transistor, said at least one counter-doping area being positioned at the level of an overlapping area between the gate region and the active area of said at least one transistor.

7. The electronic circuit according to claim 6, wherein the at least one transistor is the at least one first MOS transistor.

8. The electronic circuit according to claim 1, wherein the first conductivity type is type N, each first MOS transistor being an NMOS transistor, and the second conductivity type is type P, each second MOS transistor being a PMOS transistor.

9. The electronic circuit according to claim 1, wherein the semiconductor substrate includes silicon and the at least one first and one second insulating regions include silicon oxide.

10. The electronic circuit according to claim 1, wherein the electronic circuit is contained in an electrically erasable and programmable non-volatile memory.

11. A method, comprising:
forming a first trench insulation in a semiconductor substrate delimiting a first active area of the semiconductor substrate;
forming a second trench insulation in the semiconductor substrate delimiting a second active area of the semiconductor substrate;
recessing a top surface of the first trench insulation to a first depth below a top surface of the semiconductor substrate;
recessing a top surface of the second trench insulation to a second depth below the top surface of the semiconductor substrate;
forming a first MOS transistor of a first conductivity type at the first active region; and
forming a second MOS transistor of a second conductivity type at the second active region.

12. The method according to claim 11, comprising recessing the top surface of the second trench insulation after recessing the top surface of the first trench insulation.

13. The method according to claim 11, comprising:
forming the first and second trench insulations in a same process;
recessing the top surface of the first trench insulation to the first depth with a first etching process; and
recessing the top surface of the second trench insulation to the second depth with a second etching process after the first etching process while the first trench insulation is covered by a first mask and the second trench insulation is exposed through the first mask.

14. The method according to claim 13, wherein the first and second trench insulations are exposed to the first etching process through a second mask.

15. The method according to claim 11, wherein the first MOS transistor is a PMOS transistor and the second MOS transistor is an NMOS transistor.

16. The method according to claim 15, wherein the first trench insulation abuts the second trench insulation.

17. An integrated circuit, comprising:
a semiconductor substrate including a first active area and a second active area;
a first transistor of a first conductivity type at the first active region;
a second transistor of a second conductivity type at the second active area; and
a trench insulation defining a boundary between the first active area and the second active area and including a top surface with a step such that a first portion of the top surface of the trench insulation next to the first active area is lower than a second portion of the top surface of the trench insulation than to next to the second active area.

18. The integrated circuit according to claim 17, wherein the first transistor is an NMOS transistor and the second transistor is a PMOS transistor.

19. The integrated circuit according to claim 17 wherein the top surface of the trench insulation is below a top surface of the semiconductor substrate near the first active area, wherein the top surface of the trench insulation is substantially coplanar with the top surface of the semiconductor substrate near the second active area.

20. The integrated circuit according to claim 17, wherein the trench insulation is silicon oxide.
